(19) United States
(12) Patent Application Publication
(10) Pub. No.: US 2009/0127646 A1
(43) Pub. Date: May 21, 2009

(54) IMAGE SENSOR AND METHOD OF MANUFACTURING THE SAME

(76) Inventor: Sang Wook Ryu, Cheongju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/262,590

(22) Filed: Oct. 31, 2008

(30) Foreign Application Priority Data
Nov. 16, 2007 (KR) 10-2007-0117029

(51) Int. Cl. H01L 31/0232; H01L 31/18

(52) U.S. Cl. 257/432; 438/70; 257/E31.127

(57) ABSTRACT

An image sensor and a manufacturing method thereof are provided. The image sensor can include a semiconductor substrate having a photodiode, an interlayer dielectric layer on the semiconductor substrate, and an upper insulating layer on the interlayer dielectric layer. A trench can be provided in the upper insulating layer and the interlayer dielectric layer over the photodiode, and the trench can have a curved sidewall. A lens color filter can be disposed in the trench.

### CROSS-REFERENCE TO RELATED APPLICATION

The present application claims the benefit under 35 U.S.C. §119 to Korean Patent Application No. 10-2007-0117029, filed Nov. 16, 2007, which is hereby incorporated by reference in its entirety.

### BACKGROUND

An image sensor is a semiconductor device for converting optical images into electric signals. An image sensor is typically classified as either a charge coupled device (CCD) image sensor or a complementary metal oxide semiconductor (CMOS) image sensor (CIS).

A CIS includes a photodiode and a metal oxide semiconductor (MOS) transistor in each unit pixel. In general, a CIS sequentially detects electrical signals of each unit pixel in a switching mode to realize images.

As a design rule is gradually reduced for a CIS, the size of each unit pixel is reduced, which can lead to decreased photosensitivity. In order to enhance the photosensitivity of a CIS, a microlens is often formed on a color filter of the CIS.

However, even if a microlens is formed, the photosensitivity can still need improvement due to the optical limitations of the microlens and diffraction and scattering of light that can occur in a semiconductor device.

### BRIEF SUMMARY

Embodiments of the present invention relate to an image sensor and a manufacturing method thereof capable of improving the photosensitivity of a photodiode.

In an embodiment, an image sensor can comprise: a semiconductor substrate comprising a photodiode; an interlayer dielectric layer on the semiconductor substrate; an upper insulating layer on the interlayer dielectric layer; a trench in the upper insulating layer and the interlayer dielectric layer over the photodiode, wherein the trench has a curved sidewall; and a lens color filter disposed in the trench.

In another embodiment, a method of manufacturing an image sensor can comprise: forming a photodiode on a semiconductor substrate; forming an interlayer dielectric layer on the semiconductor substrate; forming an upper insulating layer on the interlayer dielectric layer; forming a trench in the upper insulating layer and the interlayer dielectric layer, wherein the trench has a curved sidewall; and forming a lens color filter in the trench.

### BRIEF DESCRIPTION OF THE DRAWINGS

FIGS. 1 to 5 are cross-sectional views showing a method of manufacturing an image sensor according to an embodiment of the present invention.

### DETAILED DESCRIPTION

Image sensors and manufacturing methods thereof according to embodiments of the present invention will be described in detail with reference to accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

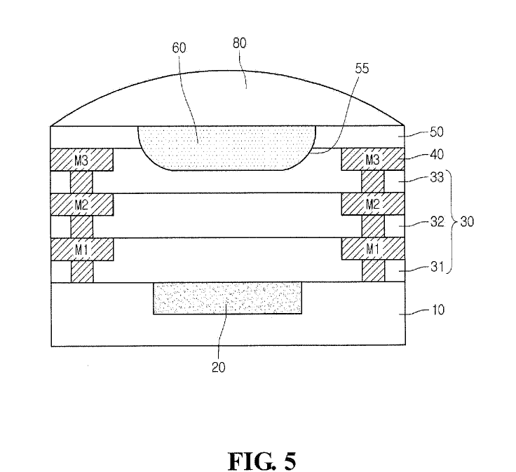

FIG. 5 is a cross-sectional view showing an image sensor according to an embodiment of the present invention.

Referring to FIG. 5, a photodiode 20 can be disposed on a semiconductor substrate 10. The photodiode 20 can be provided in a unit pixel to receive light and generate optical charges.

Although not shown, in an embodiment, a complimentary metal oxide semiconductor (CMOS) circuit, can be formed on the semiconductor substrate 10 in a unit pixel. The CMOS circuit can be connected to the photodiode 20 to receive optical charges from the photodiode 20 and convert them into electrical signals

An interlayer dielectric layer 30 can be disposed on the semiconductor substrate 10 including the photodiode 20. The interlayer dielectric layer 30 can include a metal interconnection 40.

In an embodiment, the interlayer dielectric layer 30 can include a plurality of layers. For example, the interlayer dielectric layer 30 can include a first interlayer dielectric layer 31, a second interlayer dielectric layer 32, and a third interlayer dielectric layer 33. Each interlayer dielectric layer (30, 31, 32, and 33) can be any suitable material known in the art, for example, a nitride layer or an oxide layer. Though an interlayer dielectric layer having three layers has been shown by way of example, any suitable number of interlayer dielectric layers can be included. For example, the interlayer dielectric layer 30 can include two layers or four layers.

The metal interconnection 40 can pass through the interlayer dielectric layer 30. The metal interconnection can be disposed such that it is not directly above the photodiode 20, thereby not shielding the photodiode 20 from light that may be provided to the image sensor.

In an embodiment, the metal interconnection 40 can include a plurality of metal interconnections. For example, the metal interconnection 40 can include a first metal interconnection M1, a second metal interconnection M2, and a third metal interconnection M3. The first to third metal interconnections M1, M2, and M3 can be formed in the first to third interlayer dielectric layers 31, 32, and 33, respectively. The first to third metal interconnections M1, M2, and M3 can be electrically connected to each other. Though a metal interconnection having three interconnections has been shown by way of example, any suitable number of metal interconnections can be included. For example, the metal interconnection 40 can include two interconnections or four interconnections.

An upper insulating layer 50 can be disposed on the interlayer dielectric layer 30 including the metal interconnection 40. The upper insulating layer 50 can be any suitable material known in the art, for example, an un-doped silicate glass (USG) layer.

In an embodiment, the interlayer dielectric layer 30 and the upper insulating layer 50 can each comprise an insulating material with a refractive index of from about 1.0 to about 1.45.

A trench 55 can be provided in the upper insulating layer 50 and the interlayer dielectric layer 30 above to the photodiode 20. In an embodiment, the trench 55 can be provided such that the entire photodiode 20 is under a portion of the trench 55.

The trench 55 can be provided such that portions of the upper insulating layer 50 and the interlayer dielectric layer 30 are removed. The trench 55 can have a curved sidewall.

A color filter 60 for a lens can be disposed inside the trench 55. In an embodiment, the color filter 60 can provided in the form of a convex lens with the concave portion protruding toward the photodiode 20.

The color filter 60 can be any suitable material known in the art. For example, the color filter 60 can be formed of a photosensitive material and pigments or dyes. The color filter 60 can be a red color filter, a green color filter, or a blue color filter.

In an embodiment, a microlens 80 can be disposed on the color filter 60 and the upper insulating layer. The microlens 80 can have a dome shape. In an alternative embodiment, an image sensor can be provided with no microlens.

Although not shown in the figures, in certain embodiments, a planarization layer can be disposed on the color filer 60 and the upper insulating layer 50. Then, the microlens 80 can be disposed on the planarization layer.

In an image sensor according to embodiments of the present invention, the color filter for a lens can be disposed inside the interlayer dielectric layer, allowing for better integration of a device.

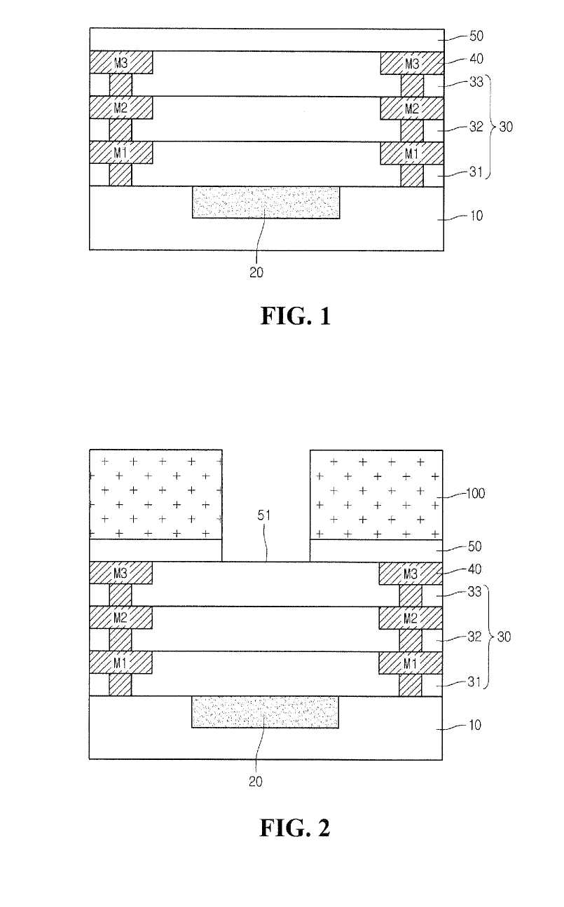

Methods of manufacturing an image sensor according to embodiments of the present invention will be described with reference to FIGS. 1 to 5.

Referring to FIG. 1, the photodiode 20 can be formed on the semiconductor substrate 10.

In an embodiment, though not shown, a CMOS circuit can be formed on the semiconductor substrate and connected to the photodiode 20 to convert optical charges received from the photodiode 20 into electrical signals in a unit pixel.

The interlayer dielectric layer 30 can be formed on the semiconductor substrate 10 including the photodiode 20. The interlayer dielectric layer 30 can include the metal interconnection 40.

In an embodiment, the interlayer dielectric layer 30 can be formed to include a plurality of layers. For example, the interlayer dielectric layer 30 can include a first interlayer dielectric layer 31, a second interlayer dielectric layer 32, and a third interlayer dielectric layer 33. Each interlayer dielectric layer (30, 31, 32, and 33) can be formed of any suitable material known in the art, for example, a nitride layer or an oxide layer. Though an interlayer dielectric layer having three layers has been shown by way of example, any suitable number of interlayer dielectric layers can be included. For example, the interlayer dielectric layer 30 can be formed of two layers or four layers.

The metal interconnection 40 can be formed of any suitable material known in the art, for example, a metal, an alloy, a conductive material containing salicide, or any combination thereof. For example, the metal interconnection 40 can include aluminum, copper, cobalt, tungsten, or any combination thereof. The metal interconnection can be disposed such that it is not directly above the photodiode 20, thereby not shielding the photodiode 20 from light that may be provided to the image sensor.

In an embodiment, the metal interconnection 40 can include a plurality of metal interconnections. For example, the metal interconnection 40 can be a first metal interconnection M1, a second metal interconnection M2, and a third metal interconnection M3. The first to third metal interconnections M1, M2, and M3 can be formed in the first to third interlayer dielectric layers 31, 32, and 33, respectively. The first to third metal interconnections M1, M2, and M3 can be electrically connected to each other. Though a metal interconnection having three interconnections has been shown by way of example, any suitable number of metal interconnections can be included. For example, the metal interconnection 40 can include two interconnections or four interconnections.

The upper insulating layer 50 can be formed on the interlayer dielectric layer 30. The upper insulating layer 50 can be formed of any suitable material known in the art, for example, an up-doped silicate glass (USG) layer. The upper insulating layer 50 can serve to help protect a device from humidity or scratching.

In an embodiment, the interlayer dielectric layer 30 and the upper insulating layer 50 can each have a refractive index of from about 1.0 to about 1.45.

Referring to FIG. 2, an auxiliary trench 51 can be formed in the upper insulating layer 50. In an embodiment, the auxiliary trench 51 can be formed to expose the interlayer dielectric layer 30. In an alternative embodiment (not shown in the figures), the auxiliary trench 51 can be formed to expose an inner portion of the upper insulating layer 50.

Additionally, the auxiliary trench 51 can be formed over the photodiode 20 such that the entire auxiliary trench 51 is over a portion of the photodiode 20.

In order to form the auxiliary trench 51, a photoresist pattern 100 can be formed on the upper insulating layer 50. Then, the upper insulating layer 50 can be etched by using the photoresist pattern 100 as an etching mask. In an embodiment, the upper insulating layer 50 can be etched through a dry etch process employing a CₓH_{y}F_{z} gas (where x, y, and z are nonnegative integers). In a further embodiment, a portion of the photoresist pattern 100 may be etched during the etching process, such that an etching ratio of the upper insulating layer 50 to the photoresist pattern 100 can be from about 2:1 to about 20:1.

In an embodiment, the opening of the photoresist pattern 100 can be less than the width of the photodiode 20. Thus, the width of the auxiliary trench 51 can be less than the width of the photodiode 20, and the entire auxiliary trench 51 can be above a portion of the photodiode 20.

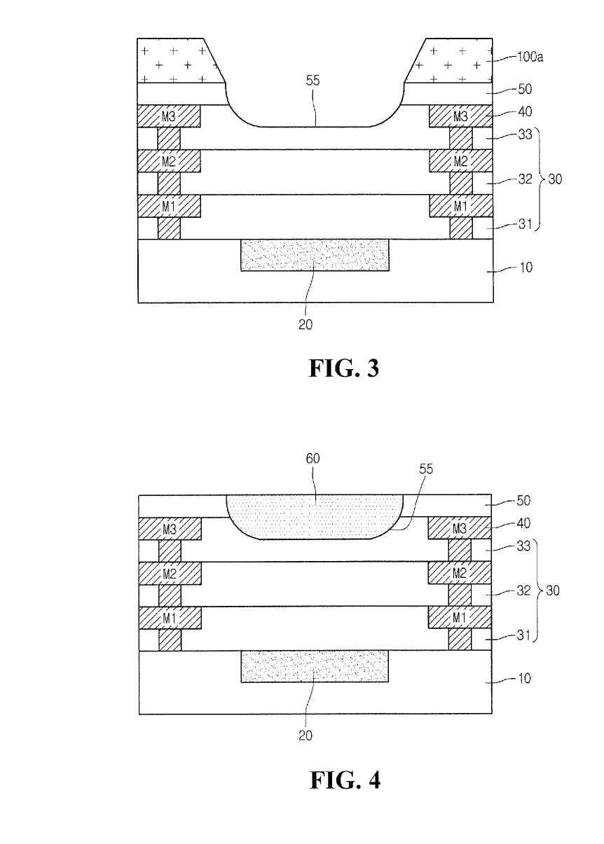

Referring to FIG. 3, the trench 55 having a curved sidewall can be formed in the third interlayer dielectric layer 30. The trench 55 can be formed to expose an inner portion of the interlayer dielectric layer 30. In an embodiment, the trench 55 can be formed such that the entire photodiode 20 is below the trench 55. That is, the width of the upper portion of the trench 55 can be larger than the width of the photodiode 20.

The trench 55 can be formed by dry-etching the interlayer dielectric layer 30 using the first photoresist pattern 100 as an etching mask. In an embodiment, the etching selectivity for the interlayer dielectric layer 30 can be reduced leading to a curved sidewall for the trench 55. For example, this can be achieved by reducing the ratio of carbon in an etching gas of the form CₓH_{y}F_{z} gas (where x, y, and z are nonnegative integers that can include 0). This can also reduce the etching ratio for the photoresist pattern 100.

That is, when the interlayer dielectric layer 30 is etched using the photoresist pattern 100 as an etching mask, the amount of carbon in the CₓH_{y}F_{z} etching gas (where x, y, and z are nonnegative integers) can be reduced or the amount of hydrogen and/or fluorine can be increased, thereby reducing the etching selectivity for the photoresist pattern 100.

In an embodiment, during etching of the interlayer dielectric layer 30 using the photoresist pattern 100 as an etching mask, CₓH_{y}F_{z} etching gas (where x, y, and z are nonnegative integers) and an oxygen-based gas can be supplied. The oxygen-based gas can be, for example, O₂ or O₃. Accordingly, the amount of carbon in the etching gas can be decreased, and the etching selectivity for the photoresist pattern 100 can be reduced. As the amount of supplied oxygen-based gas is increased, the etching ratio for the photoresist pattern 100 decreases. This is because the carbon content of the etching gas can be reduced due to chemical reaction with the oxygen-based gas to form CO or CO₂.

In another embodiment, N₂ and/or H₂ can be supplied in addition to an oxygen-based gas and the CₓH_{y}F_{z} etching gas. Thou gh a mixture of an oxygen-based gas and N₂ and/or H₂ has been described by way of example, embodiments of the present invention are not limited thereto. Any suitable mixture including an oxygen-based gas can be used.

In an embodiment, the upper insulating layer 50 and the photoresist pattern 100 can be etched with an etching ratio of from about 0.1:1 to about 3:1.

In certain embodiments, the interlayer dielectric layer 30 can be etched more quickly than the photoresist pattern 100. Thus, the interlayer dielectric layer 30 can have an etch area wider than that of a photoresist pattern 100a.

Accordingly, the trench 55 having a curved sidewall can be formed in the interlayer dielectric layer 30. In an embodiment, the trench 55 can have a width equal to or greater than the width of the photodiode 20.

Thereafter, the photoresist pattern 100a can be removed. The photoresist pattern 100a can be removed through any suitable process known in the art, for example, an ashing process.

Referring to FIG. 4, the color filter 60 for a lens can be formed in the trench 55. The color filter 60 can fill the trench 55 and therefore have a curved shape. The color filter 60 can be formed, for example, by coating a color filter material in the trench 55 through spin coating. The color filter material can be, for example, a photosensitive material and pigments or a photosensitive material and dyes. Then, the color filter material can be exposed and developed using a pattern mask (not shown). In an embodiment, the color filter 60 can be formed only inside the trench 55.

The color filter 60 can be formed in the trench 55 formed for each unit pixel, so that colors can be filtered from incident light. For example, the color filter 60 can be a red, green, or blue color filter.

In an embodiment, the color filter 60 can have a convex lens shape with the convex portion protruding toward the photodiode 20. The color filter 60 can have a refractive index higher than the refractive index of any layer of the interlayer dielectric layer 30. For example, the color filter 60 can have a refractive index of from about 1.5 to about 1.9.

Accordingly, light having passed through the color filter 60 can be collected in the photodiode 20. That is, since a lower portion of the color filter 60 can have a convex shape, and a refractive index of the color filter 60 can be higher than that of the interlayer dielectric layer 30, light having passed through the color filter 60 can be more efficiently collected in the photodiode 20.

In addition, since the color filter 60 can be formed inside the interlayer dielectric layer 30, an additional color filter is not required.

Referring to FIG. 5, the microlens 80 can be formed on the color filter 60 and the upper insulating layer 50. In an embodiment, the microlens 80 can have a dome shape. In an alternative embodiment, an image sensor can be provided with no microlens.

Although not shown in the figures, in certain embodiments, a planarization layer can be formed on the color filter 60 and the upper insulating layer 50. Then, the microlens 80 can be disposed on the planarization layer.

In a method of manufacturing an image sensor according to embodiments of the present invention, a color filter for a lens can have a curved shape with a convex portion directed toward the photodiode, thereby improving focusing efficiency of the photodiode.

In addition, the color filter can be formed inside the interlayer dielectric layer, allowing for a higher degree of integration of a semiconductor device.

Furthermore, the color filter can comprise a color filter material, so that colors can be filtered from incident light.

Additionally, in certain embodiments, the color filter can serve as a microlens, thereby reducing manufacturing time and cost.

In an embodiment, a microlens can be formed on the color filter, so that the focusing efficiency of the photodiode can be further improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate comprising a photodiode;
an interlayer dielectric layer on the semiconductor substrate;
an upper insulating layer on the interlayer dielectric layer;
a trench in the upper insulating layer and the interlayer dielectric layer over the photodiode, wherein the trench has a curved sidewall; and
a lens color filter disposed in the trench.

2. The image sensor according to claim 1, wherein the lens color filter has a refractive index higher than a refractive index of the interlayer dielectric layer.

3. The image sensor according to claim 1, wherein the upper insulating layer has a refractive index of from about 1.0 to about 1.45, and wherein the interlayer dielectric layer has a refractive index of from about 1.0 to about 1.45, and wherein the lens color filter has a refractive index of from about 1.5 to about 1.9.

4. The image sensor according to claim 1, wherein the lens color filter comprises a color filter material.

5. The image sensor according to claim 1, further comprising a microlens on the lens color filter.

6. The image sensor according to claim 1, wherein the interlayer dielectric layer comprises a metal interconnection.

7. The image sensor according to claim 1, wherein a width of the trench is larger than a width of the photodiode.

8. The image sensor according to claim 1, wherein the lens color filter completely fills the trench.

9. A method of manufacturing an image sensor, comprising:
forming a photodiode on a semiconductor substrate;
forming an interlayer dielectric layer on the semiconductor substrate;
forming an upper insulating layer on the interlayer dielectric layer;
forming a trench in the upper insulating layer and the interlayer dielectric layer, wherein the trench has a curved sidewall; and
forming a lens color filter in the trench.

10. The method according to claim 9, wherein forming the trench comprises:
forming a photoresist pattern on the upper insulating layer, wherein the photoresist pattern exposes a portion of the upper insulating layer over the photodiode;
forming an auxiliary trench by etching the upper insulating layer using the photoresist pattern as a mask; and
forming the trench by etching the upper insulating layer and the photoresist pattern after adjusting the etching conditions.

11. The method according to claim 10, wherein forming the auxiliary trench comprises using an etching gas with a formula of CₓH_{y}F_{z} (where x, y, and z are nonnegative integers).

12. The method according to claim 10, wherein forming the trench comprises using an etching gas with a formula of C_{α}H_{β}F_{γ} (where α, β, and γ are nonnegative integers), wherein α is less than β or γ.

13. The method according to claim 12, wherein forming the trench further comprises using an oxygen-based gas.

14. The method according to claim 12, wherein α is less than β and γ.

15. The method according to claim 10, wherein the auxiliary trench is formed by etching the upper insulating layer with a first etching ratio of the upper insulating layer to the photoresist pattern; and wherein adjusting the etching conditions comprises adjusting the etching conditions to obtain a second etching ratio of the upper insulating layer to the photoresist pattern, wherein the second etching ratio is different than the first etching ratio.

16. The method according to claim 15, wherein the second etching ratio of the upper insulating layer to the photoresist pattern is from about 0.1:1 to about 3:1.

17. The method according to claim 10, wherein forming the auxiliary trench by etching the upper insulating layer comprises using an etching gas with a formula of CₓH_{y}F_{z} (where x, y, and z are nonnegative integers); and wherein forming the trench comprises using an etching gas with a formula of C_{α}H_{β}F_{γ} (where α, β, and γ are nonnegative integers), wherein α is less than x.

18. The method according to claim 9, wherein the upper insulating layer comprises an oxide layer or a nitride layer, and wherein the interlayer dielectric layer comprises an oxide layer or a nitride layer, and wherein the lens color filter comprises a color filter material.

19. The method according to claim 9, wherein the upper insulating layer has a refractive index of from about 1.0 to about 1.45, and wherein the interlayer dielectric layer has a refractive index of from about 1.0 to about 1.45, and wherein the lens color filter has a refractive index of from about 1.5 to about 1.9.

20. The method according to claim 9, further comprising forming a microlens on the lens color filter.
